(19) United States
(12) Patent Application Publication
(10) Pub. No.: US 2018/0230321 A1
(43) Pub. Date: Aug. 16, 2018

(54) PRINTING INK COMPOSITION AND ELECTRONIC DEVICE

(71) Applicant: Guangzhou ChinaRay Optoelectronic Materials Ltd., Guangzhou (CN)

(72) Inventors: Junyou PAN, Guangzhou (CN); Xi YANG, Guangzhou (CN)

(21) Appl. No.: 15/751,103

(22) PCT Filed: Jul. 5, 2016
(86) PCT No.: PCT/CN2016/088641

§ 371 Date: Feb. 7, 2018

(30) Foreign Application Priority Data
Aug. 14, 2015 (CN) 2015105013089

(51) Int. Cl. C09D 11/033; C09D 11/03; C09D 11/36; C09D 11/52; C09D 11/50; C09K 11/56; C09K 11/88; C09K 11/54

(52) U.S. Cl. CPC C09D 11/033; C09D 11/03; C09D 11/36; C09D 11/52; H01L 51/502; C09K 11/565; C09K 11/883; C09K 11/54; C09D 11/50

(57) ABSTRACT

A printing ink composition comprising inorganic nano-materials. The provided printing ink composition comprises at least one inorganic nano-material, in particular, quantum dots, and at least one substituted aromatic-based or substituted heteroaromatic-based organic solvent. Also provided is an electronic device manufactured by printing with the printing ink, in particular, an electroluminescent device.

### CROSS-REFERENCES TO RELATED APPLICATIONS

This application is a national stage application of PCT Patent Application No. PCT/CN 2016/088641, filed on 5 Jul. 2016, which claims priority to Chinese Patent Application No. 201510501308.9, filed on 14 Aug. 2015, the content of all of which is incorporated herein by reference.

### FIELD OF THE INVENTION

The present invention relates to a printing ink composition comprising an inorganic nano-material, the printing ink composition comprises at least one inorganic nano-material, and at least one substituted aromatic-based or substituted heteroaromatic-based organic solvent; the present invention further relates to an electronic device manufactured by printing with the printing ink composition, specifically, an electroluminescent device.

### BACKGROUND

A plurality of kinds of inorganic nano-particle materials, due to a plurality of physicochemical properties including a nanoscale size, a shape controllable preparation and a shape adjustable through sizes, have gradually shown advantages over a plurality of inorganic bulk materials and a plurality of organic materials in a plurality of various application fields, specifically, in a field of optoelectronic material and device. Wherein, a quantum dot is a nano-sized semiconductor material with a quantum confinement effect. When stimulated by a light or electricity, the quantum dot will emit a fluorescence with a specific energy. A color (an energy) of the fluorescence is determined by a chemical composition, a size and a shape of the quantum dot. Therefore, a control of the size and shape of the quantum dot may effectively control a plurality of electrical and optical properties thereof. Currently, every country is studying an application of the quantum dots in a full-color area, mainly in a display area.

Recently, an electroluminescent device (Quantum dot Light Emitting Diodes, QLED) with the plurality of quantum dots working as a light-emitting layer has been rapidly developed, and a device feature thereof has been greatly improved, as published in Peng et al., Nature Vol 5 15 96 (2015) and Qian et al., Nature Photonics Vol 9 259 (2015). Under an electric field applied, the electroluminescent device injects an electron and a hole into a light-emitting layer respectively before combining and emitting a light. A spin-coating technology is currently a main method used to form an inorganic nanoparticles thin film. However, the spin-coating technology is hard to apply to manufacturing a large-area optoelectronic device. In a contrast, an inkjet printing may manufacture the inorganic nanoparticles thin film in a large-area and a low-cost; compared to a traditional semiconductor manufacturing process, the inkjet printing has a plurality of advantages including a low power consumption, a low water consumption, and environment friendly, which is a production technology with a great advantage and potential. A plurality of solvents applied to dissolving the inorganic nanoparticles, specifically quantum dots, traditionally, including a toluene and a chloroform, due to their low boiling points, and easy to dry, are likely to cause clogging of the injection holes, and during a film forming process in discharging or after discharge, due to a volatilization of the solvent taking away a heat of a vaporization, and lowering a temperature of a composition ejected, may cause a precipitation of an inorganic nano-material. A viscosity and a surface tension are also important parameters affecting a printing ink and a printing process thereof. A promising printing ink needs a proper viscosity and surface tension. At present, a plurality of companies has reported a plurality of quantum dot inks for printing:

Nanoco Technologies Ltd. of British, has disclosed a method of manufacturing a printable ink comprising a plurality of nanoparticles (CN101878535B). A printable nanoparticle ink and a film containing the nanoparticles accordingly, were obtained by selecting a suitable ink substrate, such as a toluene and a dodecane selenol.

Samsung Electronics has disclosed a quantum dots ink for inkjet printing (U.S. Pat. No. 8,765,014B2). The ink contains a quantum dots material in a certain concentration, an organic solvent, and a plurality of alcohol polymer additives with a high viscosity. By printing the ink, a quantum dots film is obtained, and a quantum dot electroluminescent device is prepared.

QD Vision, Inc. has disclosed a quantum dots ink formulation, the formulation comprises a host material, a quantum dots material and an additive (US2010264371A1).

A plurality of other patents related to the quantum dots ink for printing are: US2008277626A1, US2015079720A1, US2015075397A1, TW201340370A, US2007225402A1, US2008169753A1, US2010265307A1, US2015101665A1, and WO2008105792A2. In these disclosed patents, to control a plurality of physical parameters of the ink, all these quantum dots inks are containing other additives, such as an alcoholic polymer. However, introducing the additives of polymer with an insulating property may reduce an electric charge transportation capacity of the film, and have a negative impact on an optoelectronic property of the device, thus may limit a wide application thereof in an area of optoelectronic device. Therefore, finding an organic solvent system with an appropriate surface tension and viscosity for dispersing the quantum dots is particularly important.

### BRIEF SUMMARY OF THE DISCLOSURE

According to the above described defects, the purpose of the present invention is providing a new printing ink composition comprising an inorganic nano-material, the composition comprises at least one inorganic nano-material, and at least one substituted aromatic-based or substituted heteroaromatic-based organic solvent; the present invention further provides an electronic device manufactured by printing with the printing ink composition, specifically, an optoelectronic device, and more specifically, an electroluminescent device.

In order to achieve the above mentioned goals, the technical solution of the present invention to solve the technical problems is as follows:

A printing ink composition, comprises at least one inorganic nano-material and at least one substituted aromatic-based or substituted heteroaromatic-based organic solvent shown as a general formula below:

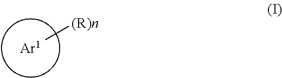

wherein, Ar¹ is an aromatic or heteroaromatic ring having 5˜10 carbon atoms, n≥1, R is a substituent, and a total number of atoms other than H of all substituents is greater than or equal to 2, wherein the organic solvents has a boiling point≥180° C., the organic solvent may be evaporated from a solvent system, before forming a thin film of inorganic nano-materials.

Wherein the organic solvent has a viscosity in a range of 1 cPs to 100 cPs at 25° C.

Wherein the organic solvent has a surface tension in a range of 19 dyne/cm to 50 dyne/cm at 25° C.

Wherein the organic solvent has a structure shown as a general formula below:

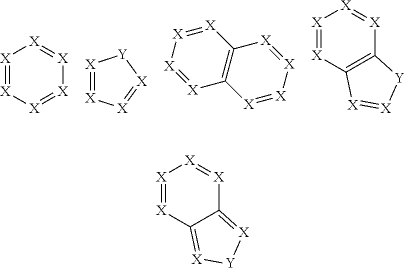

wherein,

X is CR1 or N;

Y is selected from CR2R3, SiR2R3, NR2 or, C(=0), S, or O;

R1, R2, R3 is a Hydrogen, a Deuterium, or a linear alkyl, alkoxy or thioalkoxy group having 1 to 20 of C atoms, or a branched or cyclic alkyl, alkoxy or thioalkoxy group or a silyl group having 3 to 20 of C atoms, or a substituted keto group having 1 to 20 of C atoms, an alkoxycarbonyl group having 2 to 20 of C atoms, an aryloxycarbonyl group having 7 to 20 of C atoms, a cyano group (—CN), a carbamoyl group (—C(═O)NH₂), a haloformyl group (—C(═O)—X, wherein X represents a halogen atom), a formyl group (—C(═O)—H), an isocyano group, an isocyanate group, a thiocyanate group or an isothiocyanate group, a hydroxyl group, a nitro group, a CF₃ group, a Chlorine, a Bromine, a Fluorine, a crosslinkable group or a substituted or unsubstituted aromatic or heteroaromatic ring system having 5 to 40 ring atoms, or an aryloxy or a heteroaryloxy group having 5 to 40 ring atoms, or a combination thereof, wherein one or more groups of R¹, R², R³ may form a mono or polycyclic aliphatic or aromatic ring system by themselves and/or rings bonding with the groups.

Wherein, the AR¹ in the general formula (I) is selected from a plurality of structural units below:

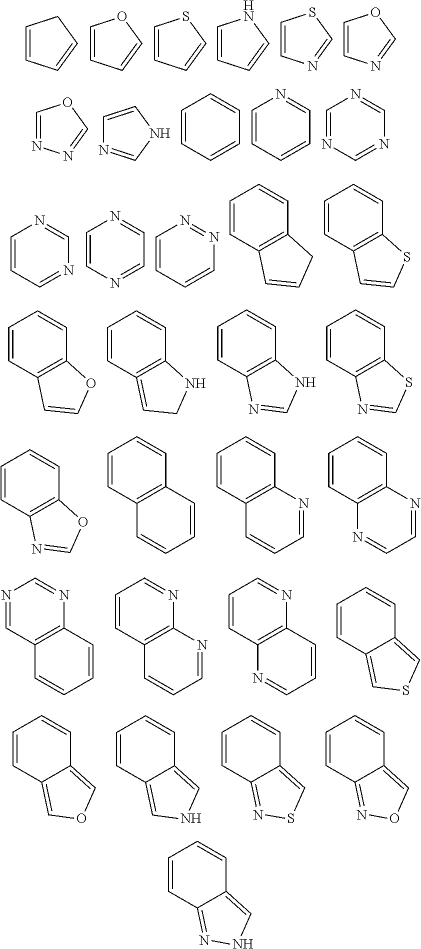

Wherein the R in the general formula (I) is selected from a linear alkyl, alkoxy or thioalkoxy group having 1 to 20 of C atoms, or a branched or cyclic alkyl, alkoxy or thioalkoxy group or a silyl group having 3 to 20 of C atoms, or a substituted keto group having 1 to 20 of C atoms, an alkoxycarbonyl group having 2 to 20 of C atoms, an aryloxycarbonyl group having 7 to 20 of C atoms, a cyano group (—CN), a carbamoyl group (—C(═O)NH₂), a haloformyl group (—C(═O)—X, wherein X represents a halogen atom), a formyl group (—C(═O)—H), an isocyano group, an isocyanate group, a thiocyanate group or an isothiocyanate group, a hydroxyl group, a nitro group, a CF₃ group, a Chlorine, a Bromine, a Fluorine, a crosslinkable group or a substituted or unsubstituted aromatic or heteroaromatic ring system having 5 to 40 ring atoms, or an aryloxy or a heteroaryloxy group having 5 to 40 ring atoms, or a combination thereof, wherein one or more groups of R may form a mono or polycyclic aliphatic or aromatic ring system by themselves and/or rings bonding with the groups.

Wherein the organic solvent is selected from: a dodecylbenzene, a dipentylbenzene, a diethylbenzene, a trimethylbenzene, a tetramethylbenzene, a butylbenzene, a tripentylbenzene, a pentyltoluene, a 1-methylnaphthalene, a dibutylbenzene, a p-diisopropylbenzene, a pentylbenzene, a tetralin, a cyclohexylbenzene, a chloronaphthalene, a 1-tetralone, a 3-phenoxytoluene, a 1-methoxynaphthalene, a cyclohexylbenzene, a dimethylnaphthalene, a 3-isopropylbiphenyl, a p-cumylbenzene, a benzyl benzoate, a dibenzyl ether, a benzyl benzoate and more, and any combinations thereof.

Wherein the organic solvent may further include at least one other solvent, while the organic solvent in the general formula (I) occupies above 50% of a total weight of a mixed solvent.

Wherein the inorganic nano-material is a quantum dot material, that is, a particle diameter thereof has a monodisperse size distribution, and a shape thereof may be selected from a plurality of different forms, including a sphere, a cube, a rod or a branched structure.

Wherein at least one luminescent quantum dot material is comprised, with a luminescence wavelength between 380 nm and 2500 nm.

Wherein the at least one inorganic nano-material is a binary or multiple semiconductor compound or a mixture thereof, in Group IV, Group II-VI, Group II-V, Group III-V, Group III-IV, Group IV-VI, Group I-III-IV, Group II-IV-VI, Group II-IV-V of the Periodic Table.

Wherein the at least one inorganic nano-material is the luminescent quantum dot, selected from CdSe, CdS, CdTe, ZnO, ZnSe, ZnS, ZnTe, HgS, HgSe, HgTe, CdZnSe, and any combinations thereof.

Wherein the at least one inorganic nano-material is the luminescent quantum dot, selected from InAs, InP, InN, GaN, InSb, InAsP, InGaAs, GaAs, GaP, GaSb, AlP, AlN, AlAs, AlSb, CdSeTe, ZnCdSe and any combinations thereof.

Wherein the at least one inorganic nano-material is a nanoparticle material of perovskite, specifically a luminescent nanoparticle material of perovskite, or a metal nanoparticle material, or a metal oxide nanoparticle material, or a plurality of combinations thereof.

Wherein at least one organic functional material is further comprised, the organic functional material may be selected from a hole injection material (HIM), a hole transport material (HTM), an electron transport material (ETM), an electron injection material (EIM), an electron blocking material (EBM), a hole blocking material (HBM), a light emitter (Emitter) and a host material (Host).

Wherein a weight ratio of the inorganic nano-material is 0.3%-70%, a weight ratio of the organic solvent contained is 30%-99.7%.

An electronic device comprises a functional layer printed by the printing ink composition described above, wherein the substituted aromatic-based or substituted heteroaromatic-based organic solvent comprised in the composition may be evaporated from the solvent system, before forming a thin film comprising the inorganic nano-materials.

Wherein the electronic device may be selected from a quantum dot light emitting diode (QLED), a quantum dot photovoltaic cell (QPV), a quantum dot light emitting electrochemical cell (QLEEC), a quantum dot field-effect transistor (QFET), a quantum dot light emitting field-effect transistor, a quantum dot laser, a quantum dot sensor and more.

Benefits:

The present invention provides a printing ink composition comprising inorganic nanoparticles, which comprises at least one inorganic nanomaterial and at least one substituted aromatic-based or substituted heteroaromatic-based organic solvent. The printing ink composition according to the present invention may adjust the viscosity and the surface tension to a suitable range for printing according to a specific printing method, specifically an ink jet printing, before forming a then film having a uniform surface. Also, the substituted aromatic-based or substituted heteroaromatic-based organic solvent may be effectively removed by a post-treatment, including a heat treatment or a vacuum treatment, which advantageously assures a performance of the electronic device. Therefore, the present invention provides a printing ink for preparing a high quality inorganic nanoparticle film, which provides a technical solution for printing an electronic or optoelectronic device.

### BRIEF DESCRIPTION OF THE DRAWINGS

FIG. 1 illustrates a structural diagram of a preferred light emitting device according to the present prevention, wherein, 101 is a substrate, 102 is an anode, 103 is a hole injection layer (HIL) or a hole transport layer (HTL), 104 is a light emitting layer, 105 is an electron injection layer (EIL) or an election transport layer (ETL), 106 is a cathode.

### DETAILED DESCRIPTION

In order to make the purpose, technical solution and the advantages of the present invention clearer and more explicit, further detailed descriptions of the present invention are stated here, referencing to the attached drawings and a plurality of preferred embodiments of the present invention. It should be understood that the detailed embodiments of the invention described here are used to explain the present invention only, instead of limiting the present invention.

The present invention provides a composition, comprising at least one inorganic nano-material and at least one substituted aromatic-based or heteroaromatic-based organic solvent shown as a general formula below:

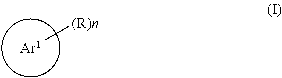

wherein, Ar¹ is an aromatic or heteroaromatic ring having 5 to 10 carbon atoms, n≥1, R is a substituent, and a total number of all atoms other than H in a substituent is greater than or equal to 2, wherein the organic solvents has a boiling point≥180° C. The organic solvent may be evaporated from a solvent system, before forming a thin film of inorganic nano-materials.

In a plurality of preferred embodiments, a substituted aromatic-based or substituted heteroaromatic-based solvent according to the general formula (I), wherein Ar1 is an aromatic or heteroaromatic ring having 5 to 10 carbon atoms. An aromatic group refers to a hydrocarbyl group containing at least one aromatic ring, including a monocyclic group and a polycyclic ring system. A heteroaromatic group refers to a hydrocarbyl group that contains at least one heteroaryl ring (heteroatoms contained), including a monocyclic group and a polycyclic ring system. The polycyclic rings may have two or more rings in which two carbon atoms are shared by two adjacent rings, that is, a condensed ring. At least one cyclic species in the polycyclic rings is aromatic or heteroaromatic.

Specifically, examples of the aromatic group are benzene, naphthalene, anthracene, phenanthrene, perylene, tetracene, pyrene, benzopyrene, triphenylene, acenaphthene, fluorene, and a plurality of derivatives thereof.

Specifically, examples of heteroaromatic groups are furan, benzofuran, thiophene, benzothiophene, pyrrole, pyrazole, triazole, imidazole, oxazole, oxadiazole, thiazole, tetrazole, indole, Azole, pyrroloimidazole, pyrrolopyrrole, thienopyrrole, thienothiophene, furanopyrrole, furofuran, thienofuran, benzisoxazole, benzisothiazole, benzimidazole, pyridine, pyrazine, pyridazine, pyrimidine, triazine, quinoline, isoquinoline, phthalonitrile, quinoxaline, phenanthridine, primary pyridine, quinazoline, quinazolinone and a plurality of derivatives thereof.

A total number of all atoms other than H in a substituent R is greater than or equal to 2. All atoms other than H in a substituent R described herein include atoms of C, Si, N, P, O, S, F, Chlorine, Bromine, I and more. For example, a methoxy substituent, three chloro substituents and more are all within a scope of the present invention, and a specific example is a 1-methoxynaphthalene or a tri chlorobenzene.

The total number of all atoms other than H in a substituent R is greater than or equal to 2, preferably is 2˜20, more preferably is 2˜10, and most preferably is 3˜10.

A composition, wherein the organic solvent has the general formula (I), a preferred embodiment may be further expressed in a general formula below:

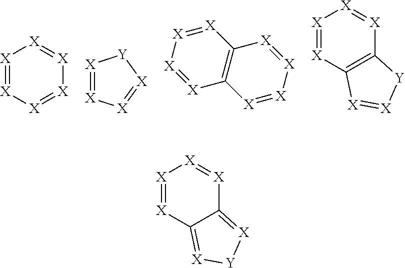

wherein,

X is CR1 or N;

Y is selected from CR2R3, SiR2R3, NR2 or, C(═O), S, or 0;

R1, R2, R³ is a Hydrogen, a Deuterium, or a linear alkyl, alkoxy or thioalkoxy group having 1 to 20 of C atoms, or a branched or cyclic alkyl, alkoxy or thioalkoxy group or a silyl group having 3 to 20 of C atoms, or a substituted keto group having 1 to 20 of C atoms, an alkoxycarbonyl group having 2 to 20 of C atoms, an aryloxycarbonyl group having 7 to 20 of C atoms, a cyano group (—CN), a carbamoyl group (—C(═O)NH₂), a haloformyl group (—C(═O)—X, wherein X represents a halogen atom), a formyl group (—C(═O)—H), an isocyano group, an isocyanate group, a thiocyanate group or an isothiocyanate group, a hydroxyl group, a nitro group, a CF₃ group, a Chlorine, a Bromine, a Fluorine, a crosslinkable group or a substituted or unsubstituted aromatic or heteroaromatic ring system having 5 to 40 ring atoms, or an aryloxy or a heteroaryloxy group having 5 to 40 ring atoms, or a combination thereof, wherein one or more groups of R¹, R², R³ may form a mono or polycyclic aliphatic or aromatic ring system by themselves and/or rings bonding with the groups.

In a plurality of preferred embodiments, R1, R2, R3 is a Hydrogen, a Deuterium, or a linear alkyl, alkoxy or thioalkoxy group having 1 to 10 of C atoms, or a branched or cyclic alkyl, alkoxy or thioalkoxy group or a silyl group having 3 to 10 of C atoms, or a substituted keto group having 1 to 10 of C atoms, an alkoxycarbonyl group having 2 to 10 of C atoms, an aryloxycarbonyl group having 7 to 10 of C atoms, a cyano group (—CN), a carbamoyl group (—C(═O)NH2), a haloformyl group (—C(═O)—X, wherein X represents a halogen atom), a formyl group (—C(═O)—H), an isocyano group, an isocyanate group, a thiocyanate group or an isothiocyanate group, a hydroxyl group, a nitro group, a CF3 group, a Chlorine, a Bromine, a Fluorine, a crosslinkable group or a substituted or unsubstituted aromatic or heteroaromatic ring system having 5 to 20 ring atoms, or an aryloxy or a heteroaryloxy group having 5 to 20 ring atoms, or a combination thereof, wherein one or more groups of R1, R2, R3 may form a mono or polycyclic aliphatic or aromatic ring system by themselves and/or rings bonding with the groups.

In a plurality of embodiments, the Ar¹ in the general formula (I) is selected from the groups listed below:

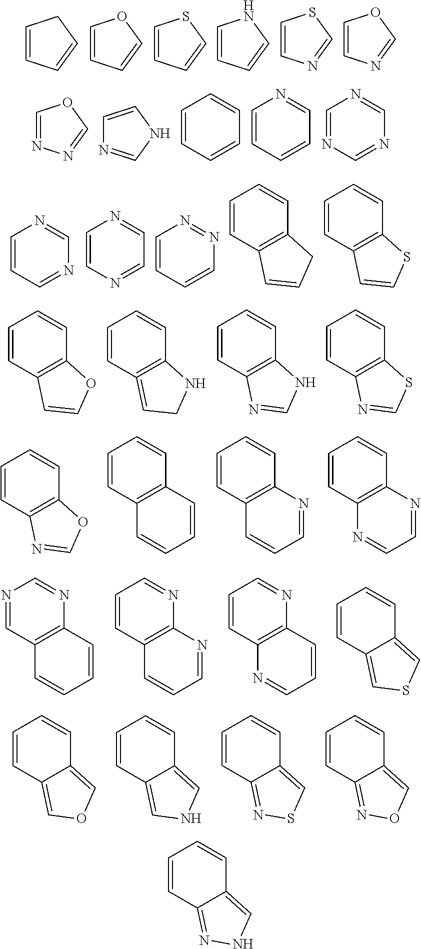

In a plurality of embodiments, at least one of the substitutes R in the general formula (I) is selected from a linear alkyl, alkoxy or thioalkoxy group having 1 to 20 of C atoms, or a branched or cyclic alkyl, alkoxy or thioalkoxy group or a silyl group having 3 to 20 of C atoms, or a substituted keto group having 1 to 20 of C atoms, an alkoxycarbonyl group having 2 to 20 of C atoms, an aryloxycarbonyl group having 7 to 20 of C atoms, a cyano group (—CN), a carbamoyl group (—C(═O)NH₂), a haloformyl group (—C(═O)—X, wherein X represents a halogen atom), a formyl group (—C(═O)—H), an isocyano group, an isocyanate group, a thiocyanate group or an isothiocyanate group, a hydroxyl group, a nitro group, a CF₃ group, a Chlorine, a Bromine, a Fluorine, a crosslinkable group or a substituted or unsubstituted aromatic or heteroaromatic ring system having 5 to 40 ring atoms, or an aryloxy or a heteroaryloxy group having 5 to 40 ring atoms, or a combination thereof, wherein one or more groups of R may form a mono or polycyclic aliphatic or aromatic ring system by themselves or rings bonding with the groups.

In a plurality of preferred embodiments, at least one of the substitutes R in the general formula (I) is selected from a linear alkyl, alkoxy or thioalkoxy group having 1 to 10 of C atoms, or a branched or cyclic alkyl, alkoxy or thioalkoxy group or a silyl group having 3 to 10 of C atoms, or a substituted keto group having 1 to 10 of C atoms, an alkoxycarbonyl group having 2 to 10 of C atoms, an aryloxycarbonyl group having 7 to 10 of C atoms, a cyano group (—CN), a carbamoyl group (—C(═O)NH2), a haloformyl group (—C(═O)—X, wherein X represents a halogen atom), a formyl group (—C(═O)—H), an isocyano group, an isocyanate group, a thiocyanate group or an isothiocyanate group, a hydroxyl group, a nitro group, a CF3 group, a Chlorine, a Bromine, a Fluorine, a crosslinkable group or a substituted or unsubstituted aromatic or heteroaromatic ring system having 5 to 20 ring atoms, or an aryloxy or a heteroaryloxy group having 5 to 20 ring atoms, or a combination thereof, wherein one or more groups of R may form a mono or polycyclic aliphatic or aromatic ring system by themselves or rings bonding with the groups.

In a plurality of preferred embodiments, the one or more groups of R in the general formula (I) may form a mono or polycyclic aliphatic or aromatic ring system by themselves or rings bonding with the groups. Examples of such a solvent include but not limited to, 1-tetralone, 2-tetralone, 1-methoxynaphthalene, 2-methoxynaphthalene, tetralin, 1-chloronaphthalene, 2-chloronaphthalene, 1, 4-dimethylnaphthalene, 1-methylnaphthalene, 2-methylnaphthalene and more.

The substituted aromatic-based or substituted heteroaromatic-based organic solvent may be capable of effectively dispersing the inorganic nanoparticles, i.e., acting as a new dispersion solvent in place of the solvent conventionally used to dispersing inorganic nanoparticles, such as a toluene, a xylene, a chloroform, a chlorine Benzene, a dichlorobenzene, an n-heptane and more.

Specifically, the substituted aromatic-based or substituted heteroaromatic-based organic solvent, applied to dispersing inorganic nanoparticles, when being selected, need to take a boiling point parameter thereof into account. In a plurality of preferred embodiments, the substituted aromatic-based or substituted heteroaromatic-based organic solvent has a boiling point no less than 180° C., in a plurality of embodiments, the substituted aromatic-based or substituted heteroaromatic-based organic solvent has a boiling point no less than 200° C., in a plurality of preferred embodiments, the substituted aromatic-based or substituted heteroaromatic-based organic solvent has a boiling point no less than 250° C., in other preferred embodiments, the substituted aromatic-based or substituted heteroaromatic-based organic solvent has a boiling point no less than 275° C. or 300° C. Boiling points within these ranges are beneficial for preventing nozzle clogging of a plurality of inkjet printheads. The substituted aromatic-based or substituted heteroaromatic-based organic solvent may be evaporated from the solvent system and forming a thin film containing the inorganic nano-materials.

A composition, wherein the organic solvent contained has a surface tension in a range of about 19 dyne/cm to 50 dyne/cm at 25° C.

Specifically, the substituted aromatic-based or substituted heteroaromatic-based organic solvent, applied to dispersing inorganic nanoparticles, when being selected, need to take a surface tension parameter thereof into account. A suitable surface tension parameter fits to a specific substrate and a specific printing method. For example, the ink jet printing, in a preferred embodiment, the substituted aromatic-based or substituted heteroaromatic-based organic solvent has a surface tension in a range of about 19 dyne/cm to 50 dyne/cm at 25° C.; in a more preferred embodiment, the substituted aromatic-based or substituted heteroaromatic-based organic solvent has a surface tension in a range of about 22 dyne/cm to 35 dyne/cm at 25° C.; in a most preferred embodiment, substituted aromatic-based or substituted heteroaromatic-based organic solvent has a surface tension in a range of about 25 dyne/cm to 33 dyne/cm at 25° C.

In a preferred embodiment, the ink according to the present invention has a surface tension in a range of about 19 dyne/cm to 50 dyne/cm at 25° C.; more preferably, at a range of about 22 dyne/cm to 35 dyne/cm; most preferably, at a range of about 25 dyne/cm to 33 dyne/cm.

A combination, wherein the organic solvent contained has a viscosity in a range of 1 cPs to 100 cPs at 25° C.

Specifically, the substituted aromatic-based or substituted heteroaromatic-based organic solvent, applied to dispersing inorganic nanoparticles, when being selected, need to take a viscosity parameter of the ink thereof into account. The viscosity may be adjusted through a plurality of different ways, including selecting a suitable organic solvent and a concentration of the nano-materials in the ink. The solvent system comprising the substituted aromatic-based or substituted heteroaromatic-based organic solvent according to the present invention may facilitate people to adjust the printing ink in a suitable range according to the printing method applied. Generally, a weight ratio of the inorganic nano-material contained in the printing ink according to the present invention is in a range of 0.3%-70 wt %, preferably, in a range of 0.5%-50 wt %, more preferably, in a range of 0.5%-30 wt %, most preferably, in a range of 1%-10 wt %. In a preferred embodiment, the printing ink containing the substituted aromatic-based or substituted heteroaromatic-based organic solvent has a viscosity lower than 100 cPs according to the composition ratio; in a more preferred embodiment, the printing ink containing the substituted aromatic-based or substituted heteroaromatic-based organic solvent has a viscosity lower than 50 cPs according to the composition ratio; in a most preferred embodiment, the substituted aromatic-based or substituted heteroaromatic-based organic solvent has a viscosity in a range between 1.5 to 20 cPs according to an above composition ratio. The printing ink prepared in such a way will be specifically suitable for ink jet printing.

The ink obtained from the solvent system comprising the substituted aromatic-based or substituted heteroaromatic-based organic solvent satisfying the boiling points and the surface tension parameters and the viscosity parameters may form the inorganic nanoparticles thin film with a uniform thickness and composition property.

Examples of the substituted aromatic-based or substituted heteroaromatic-based organic solvent according to the present invention are, but not limited to, 1-tetralone, 3-phenoxytoluene, acetophenone, 1-methoxynaphthalene, p-diisopropylbenzene, pentylbenzene, tetralin, cyclohexylbenzene, chloronaphthalene, 1,4-dimethylnaphthalene, 3-isopropylbiphenyl, p-cumylbenzene, dypentylbenzene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, 1-methylnaphthalene, 1,2,4-trichlorobenzene, 1,3-dipropoxybenzene, 4,4-difluorodiphenylmethane, diphenyl ether, 1, 2-dimethoxy-4-(1-propenyl) benzene, diphenylmethane, 2-phenylpyridine, 3-phenylpyridine, 2-phenoxymethyl ether, 2-phenoxytetrahydrofuran, 2-naphthyl ether, N-methyldiphenylamine, 4-isopropylbiphenyl, α, α-dichlorodiphenylmethane, 4-(3-phenylpropyl) pyridine, benzyl benzoate, 1,1-bis (3,4-dimethylphenyl) ethane, 2-isopropylnaphthalene, dibenzyl ether and more.

A table below shows the boiling points, surface tension and viscosity parameters of part of the above examples:

| | | | Surface | |
|---|---|---|---|---|
| | | Boiling | tension | Viscosity |
| | | point | @RT | @RT |
| Compound | Structure formula | (° C.) | (dyne/cm) | (cPs) |
| 1-tetralone | 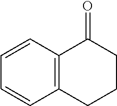 [SMILES: O=C1CCCc2ccccc21] | 256 | 42 | 8.6 |
| 3-phenoxytoluene | 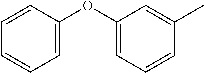 | 272 | 37.4 | 5 |
| acetophenone | 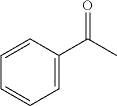 | 202 | 39 | 1.6 |
| 1-methoxynaphthalene | 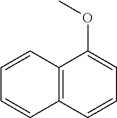 | 270 | 43 | 7.2 |
| p-diisopropylbenzene | 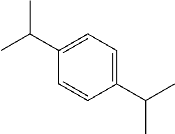 | 210 | 28.3 | 1.2 |
| pentylbenzene | 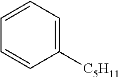 | 205 | 30.4 | 1.3 |
| tetralin | 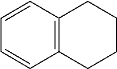 | 207 | 35.9 | 2 |
| cyclohexylbenzene | 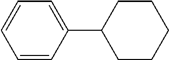 [SMILES: c1ccc(C2CCCCC2)cc1] | 238 | 34 | 4 |
| chloronaphthalene | 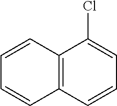 [SMILES: Clc1cccc2ccccc12] | 360 | 43 | 3 |
| 1,4- dimethylnaphthalene | 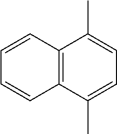 | 268 | 40 | 6 |
| 3-isopropylbiphenyl | 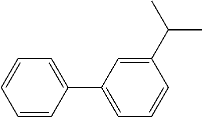 | 296 | 34 | 9 |
| p-methylcumene | 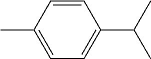 | 177 | 28.8 | 3.4 |
| dipentylbenzene | 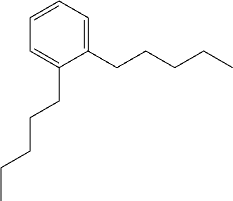 [SMILES: CCCCCc1ccccc1CCCCC] | 255- | 30 | 4.7 |
| o-diethylbenzene | 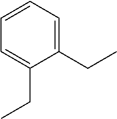 | 183 | 30 | 3.8 |
| m-diethylbenzene | 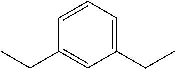 | 181 | 29 | 1.24 |
| p-diethylbenzene | 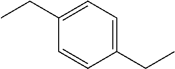 | 183 | 29 | 3.6 |
| 1,2,3,4- tetramethylbenzen | 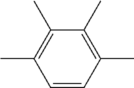 | 205 | 29 | 2 |
| 1,2,3,5- tetramethylbenzen | 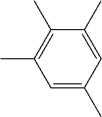 | 205 | 29 | 2 |
| 1,2,4,5-,4- tetramethylbenzen | 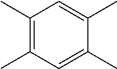 | 197 | 29 | 2 |
| Butylbenzene | 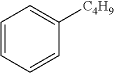 | 183 | 29.23 | 1 |
| dodecylbenzene | 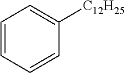 | 331 | 30.12 | 5.4 |
| 1-methylnaphthalene | 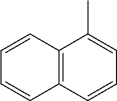 | 240 | 38 | 3 |
| 1,2,4-trichlorobenzene | 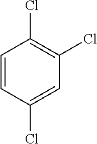 | 214 | 31 | 1.6 |
| diphenyl ether | 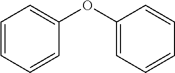 [SMILES: c1ccc(Oc2ccccc2)cc1] | 257 | 38 | 3.5 |
| diphenylmethane | 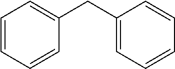 [SMILES: c1ccc(Cc2ccccc2)cc1] | 265 | 37 | 1.5 |
| 4-isopropylbiphenyl | 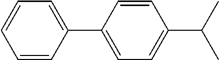 | 298 | 34 | 9 |
| benzyl benzoate | 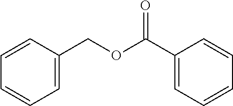 [SMILES: O=C(OCc1ccccc1)c1ccccc1] | 324 | 44 | 8.3 |
| 1,1-bis(3,4- dimethylphenyl) ethane | 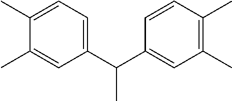 | 333 | 34 | 10 |
| 2- isopropylnaphthalene | 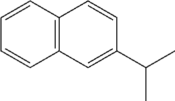 | 268 | 36 | 4 |
| dibenzyl ether | 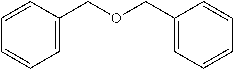 [SMILES: c1ccc(COCc2ccccc2)cc1] | 298 | 39 | 8.7 |

In a preferred embodiment, the substituted aromatic-based or substituted heteroaromatic-based organic solvent are selected from: dodecylbenzene, dipentylbenzene, diethylbenzene, trimethylbenzene, tetramethylbenzene, tripentylbenzene, pentyltoluene, 1-methylnaphthalene, dihexylbenzene, dibutylbenzene, p-diisopropylbenzene, pentylbenzene, tetralin, cyclohexylbenzene, chloronaphthalene, 1-tetralone, 3-phenoxytoluene, 1-methoxynaphthalene, cyclohexylbenzene, dimethylnaphthalene, 3-isopropyl Biphenyl, p-cumyl, benzyl benzoate, dibenzyl ether, benzyl benzoate and more, and any combinations thereof.

In a plurality of preferred embodiments, the printing ink composition of the present invention contains a single substituted aromatic-based or substituted heteroaromatic-based organic solvent.

In a plurality of other preferred embodiments, the printing ink composition of the present invention contains a mixture of two kinds of or over two kinds of the substituted aromatic-based or substituted heteroaromatic-based organic solvent.

In a plurality of other preferred embodiments, the substituted aromatic-based or substituted heteroaromatic-based organic solvent adopted by the printing ink composition in the present invention may further include at least one other solvent, and the organic solvent contained of the general formula (I) occupies over 50% of the total weight of a mixed solvent. Preferably, the organic solvent contained of the general formula (I) occupies at least 70% of the total weight of the mixed solvent; more preferably, the organic solvent contained of the general formula (I) occupies at least 90% of the total weight of the mixed solvent; Most preferably, the substituted aromatic-based or substituted heteroaromatic-based organic solvent contains at least 99% of the organic solvent of the general formula (I) by weight, or consists essentially of, or entirely of the organic solvent of the general formula (I).

In a preferred embodiment, the substituted aromatic-based or substituted heteroaromatic-based organic solvent adopted by the printing ink composition in the present invention is a dodecylbenzene.

In another preferred embodiment, the substituted aromatic-based or substituted heteroaromatic-based organic solvent adopted by the printing ink composition in the present invention is a mixture of the dodecylbenzene and at least one other solvent, and the dodecylbenzene occupies at least 50% of the total weight of the mixed solvent; preferably, the dodecylbenzene occupies at least 70% of the total weight of the mixed solvent; more preferably, the dodecylbenzene occupies at least 90% of the total weight of the mixed solvent.

In a preferred embodiment, the substituted aromatic-based or substituted heteroaromatic-based organic solvent adopted by the printing ink composition of the present invention is the 1-tetralone.

In another preferred embodiment, the substituted aromatic-based or substituted heteroaromatic-based organic solvent adopted by the printing ink composition of the present invention is a mixture of the 1-tetralone and at least one other solvent, and the 1-tetralone occupies at least 50% of the total weight of the mixed solvent; preferably, the 1-tetralone occupies at least 70% of the total weight of the mixed solvent; more preferably, the 1-tetralone occupies at least 90% of the total weight of the mixed solvent.

In a preferred embodiment, the substituted aromatic-based or substituted heteroaromatic-based organic solvent adopted by the printing ink composition of the present invention is the 3-phenoxytoluene.

In another preferred embodiment, the substituted aromatic-based or substituted heteroaromatic-based organic solvent adopted by the printing ink composition of the present invention is a mixture of the 3-phenoxytoluene and at least one other solvent, and the 3-phenoxytoluene occupies at least 50% of the total weight of the mixed solvent; preferably, the 3-phenoxytoluene occupies at least 70% of the total weight of the mixed solvent; more preferably, the 3-phenoxytoluene occupies at least 90% of the total weight of the mixed solvent.

In a preferred embodiment, the substituted aromatic-based or substituted heteroaromatic-based organic solvent adopted by the printing ink composition of the present invention is the 3-isopropylbiphenyl.

In another preferred embodiment, the substituted aromatic-based or substituted heteroaromatic-based organic solvent adopted by the printing ink composition of the present invention is a mixture of the 3-isopropylbiphenyl and at least one other solvent, and the 3-phenoxytoluene occupies at least 50% of the total weight of the mixed solvent; preferably, the 3-isopropylbiphenyl occupies at least 70% of the total weight of the mixed solvent; more preferably, the 3-isopropylbiphenyl occupies at least 90% of the total weight of the mixed solvent.

In a preferred embodiment, the substituted aromatic-based or substituted heteroaromatic-based organic solvent adopted by the printing ink composition of the present invention is the cyclohexylbenzene.

In another preferred embodiment, the substituted aromatic-based or substituted heteroaromatic-based organic solvent adopted by the printing ink composition of the present invention is a mixture of the cyclohexylbenzene and at least one other solvent, and the cyclohexylbenzene occupies at least 50% of the total weight of the mixed solvent; preferably, the cyclohexylbenzene occupies at least 70% of the total weight of the mixed solvent; more preferably, the cyclohexylbenzene occupies at least 90% of the total weight of the mixed solvent.

In a preferred embodiment, the substituted aromatic-based or substituted heteroaromatic-based organic solvent adopted by the printing ink composition of the present invention is the 1-methoxynaphthalene.

In another preferred embodiment, the substituted aromatic-based or substituted heteroaromatic-based organic solvent adopted by the printing ink composition of the present invention is a mixture of the 1-methoxynaphthalene and at least one other solvent, and the 1-methoxynaphthalene occupies at least 50% of the total weight of the mixed solvent; preferably, the 1-methoxynaphthalene occupies at least 70% of the total weight of the mixed solvent; more preferably, the 1-methoxynaphthalene occupies at least 90% of the total weight of the mixed solvent.

In a preferred embodiment, the substituted aromatic-based or substituted heteroaromatic-based organic solvent adopted by the printing ink composition of the present invention is the 1,4-dimethylnaphthalene.

In another preferred embodiment, the substituted aromatic-based or substituted heteroaromatic-based organic solvent adopted by the printing ink composition of the present invention is a mixture of the 1,4-dimethylnaphthalene and at least one other solvent, and the 1,4-dimethylnaphthalene occupies at least 50% of the total weight of the mixed solvent; preferably, the 1,4-dimethylnaphthalene occupies at least 70% of the total weight of the mixed solvent; more preferably, the 1,4-dimethylnaphthalene occupies at least 90% of the total weight of the mixed solvent.

In a preferred embodiment, the substituted aromatic-based or substituted heteroaromatic-based organic solvent adopted by the printing ink composition of the present invention is the p-methylcumene.

In another preferred embodiment, the substituted aromatic-based or substituted heteroaromatic-based organic solvent adopted by the printing ink composition of the present invention is a mixture of the p-methylcumene. and at least one other solvent, and the p-methylcumene occupies at least 50% of the total weight of the mixed solvent; preferably, the p-methylcumene. occupies at least 70% of the total weight of the mixed solvent; more preferably, the p-methylcumene. occupies at least 90% of the total weight of the mixed solvent.

In a preferred embodiment, the substituted aromatic-based or substituted heteroaromatic-based organic solvent adopted by the printing ink composition of the present invention is the diethylbenzene.

In another preferred embodiment, the substituted aromatic-based or substituted heteroaromatic-based organic solvent adopted by the printing ink composition of the present invention is a mixture of the diethylbenzene and at least one other solvent, and the diethylbenzene occupies at least 50% of the total weight of the mixed solvent; preferably, the diethylbenzene occupies at least 70% of the total weight of the mixed solvent; more preferably, the diethylbenzene occupies at least 90% of the total weight of the mixed solvent.

In a preferred embodiment, the substituted aromatic-based or substituted heteroaromatic-based organic solvent adopted by the printing ink composition of the present invention is the dibenzyl ether.

In another preferred embodiment, the substituted aromatic-based or substituted heteroaromatic-based organic solvent adopted by the printing ink composition of the present invention is a mixture of the dibenzyl ether and at least one other solvent, and the dibenzyl ether occupies at least 50% of the total weight of the mixed solvent; preferably, the dibenzyl ether occupies at least 70% of the total weight of the mixed solvent; more preferably, the dibenzyl ether occupies at least 90% of the total weight of the mixed solvent.

In a plurality of other embodiments, the printing ink further comprises another organic solvent. An example of the organic solvent includes (but not limited to): methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2,-tetrachloroethane, ethyl acetate, butyl acetate, dimethylformamide, dimethylacetamide, dimethyl sulfoxide, tetralin, decalin, indene and/or a mixture thereof.

The printing ink may contain additionally one or more components such as a surface-active compound, a lubricant, a wetting agent, a dispersant, a hydrophobic agent, an adhesive and more, to adjust the viscosity or a film-forming property, to improve an adhesion, and more.

The printing ink may be deposited to obtain the quantum dot film by a plurality of techniques. A suitable printing or coating technique includes, but not limited to, an inkjet printing, a nozzle printing, a typography, a screen printing, a dip-coating, a spin-coating, a blade coating, a roller printing, a reverse-roll printing, a offset lithography printing, a flexography, a web printing, a spray coating, a brush coating or a pad printing, a slot-die coating and more. A preferred printing technique is gravure printing, a jet printing and an ink jet printing. For more information on the printing techniques and associated ink requirements thereof, such as a solvent and a concentration, a viscosity, etc., it may be referenced to Handbook of Print Media: Technologies and Production Methods, ISBN 3-540-67326-1, edited by Helmut Kipphan. In general, a different printing technology has a different character requirement for the ink used. For example, a printing ink suitable for the ink-jet printing needs to regulate a surface tension, a viscosity, and a wettability of the ink so that the ink may be discharged well through a nozzle at a printing temperature (such as a room temperature, 25° C.) instead of being dried out on the nozzle or blocking the nozzle, or form a continuous, smooth and defect-free film on a specific substrate.

The printing ink according to the present invention contains at least one inorganic nano-material.

In a preferred embodiment, the printing ink, wherein the at least one inorganic nanomaterial is preferably an inorganic semiconductor nanoparticle material.

In a plurality of embodiments, an average particle size of the inorganic nano-material is in a range about 1 to 1000 nm. In a certain preferred embodiment, the average particle size of the inorganic nano-material is in a range about 1 to 100 nm. In a certain more preferred embodiment, the average particle size of the inorganic nano-material is in a range about 1 to 20 nm, and most preferably, in a range of 1 to 10 nm.

The inorganic nano-material may be selected from a plurality of different shapes, including but not limited to a plurality of different nano-topographies including a sphere, a cube, a rod, a disk or a branched structure, and a mixture of various shaped particles.

In a preferred embodiment, the inorganic nano-material is a quantum dot material, having a very narrow and monodisperse size distribution, that is, a difference in dimension between the particles is very small. Preferably, the monodisperse quantum dots have a root mean square deviation (RMSD) in dimension less than 15% rms; more preferably, the monodisperse quantum dots have a RMSD in dimension less than 10% rms; and most preferably, the monodisperse quantum dots have a RMSD in dimension less than 5% rms.

In a preferred embodiment, the inorganic nano-material is a luminescent material.

In a plurality of more preferred embodiments, the inorganic nano-material is a quantum dot luminescent material.

In general, a luminescent quantum dot may emit a light at a wavelength between 380 nm and 2500 nm. For example, it has been found that, an emission wavelength of the quantum dot having a CdS core lies in a range of about 400 to 560 nm; an emission wavelength of a quantum dot having a CdSe core lies in a range of about 490 to 620 nm; an emission wavelength of a quantum dot having a CdTe core lies in a range of about 620 nm to 680 nm; an emission wavelength of a quantum dot having an InGaP core lies in a range of about 600 nm to 700 nm; an emission wavelength of a quantum dot having a PbS core lies in a range of about 800 nm to 2500 nm; an emission wavelength of a quantum dot having a PbSe core lies in a range of about 1200 nm to 2500 nm; an emission wavelength of a quantum dot having a CuInGaS core lies in a range of about 600 nm to 680 nm; an emission wavelength of a quantum dot having a ZnCuInGaS core lies in a range of about 500 nm to 620 nm; an emission wavelength of a quantum dot having a CuInGaSe core lies in a range of about 700 nm to 1000 nm;

In a preferred embodiment, the quantum dot material comprises at least one capable of emitting a blue light having an emission peak wavelength of 450 nm to 460 nm or a green light having an emission peak wavelength of 520 nm to 540 nm, or a red light having an emission peak wavelength of 615 nm to 630 nm, or a mixture thereof.

The quantum dots contained may be selected with a specific chemical composition, topography, and/or size, to achieve emitting the light in a desired wavelength under an electrical stimulation. A relationship between a luminescent property of a quantum dot and a chemical composition, topography and/or size thereof may be found in Annual Review of Material Science, 2000, 30, 545-610; Optical Materials Express, 2012, 2, 594-628; Nano Res, 2009, 2, 425-447. Entire contents of the patent documents listed above are hereby incorporated by reference.

A narrow particle size distribution of the quantum dots enables the quantum dots to have a narrower emission spectra (J. Am. Chem. Soc., 1993, 115, 8706; US 20150108405). In addition, according to a different chemical composition and structure employed, the size of the quantum dots must be adjusted accordingly within the size range described above, to achieve the luminescence properties of a desired wavelength.

Preferably, the luminescent quantum dot is a semiconductor nanocrystal. In one embodiment, the size of the semiconductor nanocrystals is in a range of about 5 nm to about 15 nm. In addition, according to the different chemical composition and structure employed, the size of the quantum dots must be adjusted accordingly within the size range described above, to achieve the luminescence properties of a desired wavelength.

The semiconductor nanocrystal includes at least one semiconductor material, wherein the semiconductor material may be selected from a binary or multiple semiconductor compound or a mixture thereof, in group IV, group II-VI, group II-V, group III-V, group III-VI, group IV-VI, group I-III-VI, group II-IV-VI, group II-IV-V of a Periodic Table. Specifically, an example of the semiconductor material includes, but are not limited to, a group IV semiconductor compound, composed by a single elemental Si, Ge, C and a binary compound SiC, SiGe; a group II-VI semiconductor compound, consisting of a plurality of binary compounds including CdSe, CdTe, CdO, CdS, CdSe, ZnS, ZnSe, ZnTe, ZnO, HgO, HgS, HgSe, HgTe, a plurality of ternary compounds including CdSeS, CdSeTe, CdSTe, CdZnS, CdZnSe, CdZnTe, CgHgS, CdHgSe, ZnSeS, ZnSeTe, ZnSTe, HgSeS, HgSeTe, HgSTe, HgZnS, HgSeSe, and a plurality of quaternary compounds including CgHgSeS, CdHgSeTe, CgHgSTe, CdZnSeS, CdZnSeTe, HgZnSeTe, HgZnSTe, CdZnSTe, HgZnSeS; a group III-V semiconductor compound, consisting of a plurality of binary compounds including AlN, AlP, AlAs, AlSb, GaN, GaP, GaAs, GaSb, InN, InP, InAs, InSb, a plurality of ternary compounds including AlNP, AlNAs, AlNSb, AlPAs, AlPSb, GaNP, GaNAs, GaNSb, GaPAs, GaPSb, InNP, InNAs, InNSb, InPAs, InPSb, a plurality of quaternary compounds including GaAlNAs, GaAlNSb, GaAlPAs, GaInNP, GaInNAs, GaInNSb, GaInPAs, GaInPSb, InAlNP, InAlNAs, InAlNSb, InAlPAs, InAlPSb, a group IV-VI semiconductor compound, consisting of a plurality of binary compounds including SnS, SnSe, SnTe, PbSe, PbS, PbTe, a plurality of ternary compounds including SnSeS, SnSeTe, SnSTe, SnPbS, SnPbSe, SnPbTe, PbSTe, PbSeS, PbSeTe, and a plurality of quaternary compounds including SnPbSSe, SnPbSeTe, SnPbSTe.

In a preferred embodiment, the luminescent quantum dots comprise a semiconductor material of groups II-VI, preferably selected from CdSe, CdS, CdTe, ZnO, ZnSe, ZnS, ZnTe, HgS, HgSe, HgTe, CdZnSe, and any combinations thereof. In a proper embodiment, since a synthesis of CdSe is relatively mature, the material is thus used as a luminescent quantum dot for a visible light.

In another preferred embodiment, the luminescent quantum dots comprise a semiconductor material of groups III-V, preferably selected from InAs, InP, InN, GaN, InSb, InAsP, InGaAs, GaAs, GaP, GaSb, AlP, AlN, AlAs, AlSb, CdSeTe, ZnCdSe and any combinations thereof.

In another preferred embodiment, the luminescent quantum dots comprise a semiconductor material of groups IV-VI, preferably selected from PbSe, PbTe, PbS, PbSnTe, TI2SnTe5, and any combinations thereof.

In a preferred embodiment, the quantum dot is a core-shell structure. Each of both the core and the shell comprises one or more semiconductor materials, either identical or different, respectively.

The core of the quantum dots may be selected from a binary or multiple semiconductors compound in the group IV, group II-VI, group II-V, group III-V, group III-VI, group IV-VI, group I-III-VI, group II-IV-VI, group II-IV-V of a Periodic Table. Specifically, an embodiment on the core of the quantum dots includes but not limited to ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, PbSe, PbTe, Ge, Si, or an alloy or a mixture of any combinations thereof.

The shell of the quantum dots may be selected from a plurality of semiconductor materials, identical or different from the core. The semiconductor materials may be used for the shell include a binary or multiple semiconductor compound in the group IV, group II-VI, group II-V, group III-V, group III-VI, group IV-VI, group I-III-VI, group II-IV-VI, group II-IV-V of a Periodic Table. Specifically, an embodiment on the shell of the quantum dots includes but not limited to ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, PbSe, PbTe, Ge, Si, or an alloy or a mixture of any combinations thereof.

The quantum dot in the core-shell structure, wherein, the shell may include a single-layer or multi-layer structure. The shell includes one or more semiconductor materials that are identical or different from the core. In a preferred embodiment, the shell has a thickness of about 1 to 20 layers. In a more preferred embodiment, the shell has a thickness of about 5 to 10 layers. In a plurality of embodiments, on a surface of the core of the quantum dot, two or more shells are comprised.

In a preferred embodiment, the semiconductor material used for the shell has a larger bandgap than the core. Specifically, the core-shell has a type I semiconductor heterojunction structure.

In another preferred embodiment, the semiconductor material used for the shell has a smaller bandgap than the core.

In a preferred embodiment, the semiconductor material used for the shell has an atomic crystal structure that is the same as or close to the core. Such a choice helps to reduce a stress between the core and the shell, while making the quantum dots more stable.

In a preferred embodiment, the quantum dots with the core-shell structure adopted are, but not limited to:

Red light: CdSe/CdS, CdSe/CdS/ZnS, CdSe/CdZnS and more,

Green light: CdZnSe/CdZnS, CdSe/ZnS and more,

Blue light: CdS/CdZnS, CdZnS/ZnS and more.

A preferred method for preparing the quantum dots is a colloidal growth method. In a preferred embodiment, a method for preparing a monodisperse quantum dot is selected from a hot-inject method and/or a heating-up method. The method for preparation is disclosed in a reference in Nano Res, 2009, 2, 425-447; Chem. Mater., 2015, 27 (7), pp 2246-2285. The entire contents of the documents listed above are hereby incorporated by reference.

In a preferred embodiment, the surface of the quantum dot contains a plurality of organic ligands. An organic ligand may control a growth of the quantum dots, control an appearance of the quantum dots and reduce a surface defect of the quantum dots, so as to improve a luminous efficiency and stability of the quantum dots. The organic ligand may be selected from a pyridine, a pyrimidine, a furan, an amine, an alkylphosphine, an alkylphosphine oxide, an alkylphosphonic acid or an alkylphosphinic acid, an alkylthiol and more. Examples of specific organic ligands include, but are not limited to, tri-n-octylphosphine, tri-n-octylphosphine oxide, trihydroxypropylphosphine, tributylphosphine, tridodecylphosphine, dibutyl phosphite, tributyl phosphite, octadecyl phosphite, trilauryl phosphite, didodecyl phosphite, triisodecyl phosphite, bis (2-ethylhexyl) phosphate, tridecyl phosphate, hexadecylamine, oleylamine, octadecylamine, dioctadecylamine, octacosamine, bis (2-ethylhexyl) amine, octylamine, dioctylamine, trioctylamine, dodecylamine, didodecylamine, didodecylamine, hexadecylamine, phenylphosphoric acid, hexylphosphoric acid, tetradecylphosphonic acid, octyl phosphoric acid, n-octadecylphosphonic acid, propenyldiphosphonic acid, dioctyl ether, Diphenyl ether, octyl mercaptan, dodecyl mercaptan.

In another preferred embodiment, the surface of the quantum dot contains a plurality of inorganic ligands. The quantum dots protected by inorganic ligands may be obtained by ligand exchange of organic ligands on the surface of the quantum dots. Specifically, an embodiment on inorganic ligands includes but not limited to: S2-, HS—, Se2-, HSe—, Te2-, HTe—, TeS32-, OH—, NH2-, PO43-, MoO42-, and more. An example on such an inorganic ligand quantum dot may refer to a document of J. Am. Chem. Soc. 2011, 133, 10612-10620; ACS Nano, 2014, 9, 9388-9402. All contents of the documents listed above are hereby incorporated for a reference.

In a plurality of embodiments, the surface of the quantum dots has one or more identical or different ligands.

In a preferred embodiment, a luminescence spectrum exhibited by a monodisperse quantum dot has a symmetrical peak shape and a narrow peak width at half height. Generally, the better a monodispersity of the quantum dots is, the more symmetrical a luminescence peak is, and the narrower the peak width at half height is. Preferably, the peak width at half height of the quantum dot is less than 70 nm; more preferably, the peak width at half height of the quantum dot is less than 40 nm; and most preferably, the peak width at half height of the quantum dot is less than 30 nm.

The quantum dots have a luminous quantum efficiency of 10%-100%. Preferably, the quantum dots have a luminous quantum efficiency of more than 50%; more preferably the quantum dots have a luminous quantum efficiency of more than 80%; most preferably, the quantum dots have a luminous quantum efficiency of more than 90%.

A plurality of other materials, techniques, methods, applications, and other information concerning the quantum dots that may be useful in the present invention are described in a plurality of patent documents following: WO2007/117698, WO2007/120877, WO2008/108798, WO2008/105792, WO2008/111947, WO2007/092606, WO2007/117672, WO2008/033388, WO2008/085210, WO2008/13366, WO2008/063652, WO2008/063653, WO2007/143197, WO2008/070028, WO2008/063653, U.S. Pat. No. 6,207,229, U.S. Pat. No. 6,251,303, U.S. Pat. No. 6,319,426, U.S. Pat. No. 6,426,513, U.S. Pat. No. 6,576,291, U.S. Pat. No. 6,607,829, U.S. Pat. No. 6,861,155, U.S. Pat. No. 6,921,496, U.S. Pat. No. 7,060,243, U.S. Pat. No. 7,125,605, U.S. Pat. No. 7,138,098, U.S. Pat. No. 7,150,910, U.S. Pat. No. 7,470,379, U.S. Pat. No. 7,566,476, WO2006134599A1. All contents of the documents listed above are hereby incorporated for a reference.

In another preferred embodiment, a luminescent semiconductor nanocrystal is a nanorod. A characteristics of the nanorods is different from a spherical nanocrystal. For example, the luminescence of a nanorod is polarized along a long rod axis while the luminescence of a spherical crystal is unpolarized (refer to Woggon et al., Nano Lett., 2003, 3, p 509). The nanorod has an excellent characteristic on an optical gain that makes them potentially useful as a laser gain material (refer to Banin et al., Adv. Mater. 2002, 14, p 317). Additionally, the luminescence of a nanorod may be switched on and off reversibly under a control of an external electric field (refer to Banin et al., Nano Lett. 2005, 5, p 1581). A plurality of these characteristics of the nanorods may be preferentially incorporated into a device of the present invention, in a plurality of cases. An example of preparing a semiconductor nanorod includes: WO03097904A1, US2008188063A1, US2009053522A1, KR20050121443A. All contents of the documents listed above are hereby incorporated for a reference.

In other preferred embodiments, the printing ink according to the present invention, wherein, the inorganic nano-material is a nanoparticle material of perovskite, specifically, a luminescent nanoparticle material of perovskite.

The nanoparticle material of perovskite has a general formula of AMX3, wherein A may be selected from an organic amine or an alkali metal cation, M may be selected from a metal cation, X may be selected from an oxygen atom or a halogen anion. A specific embodiment includes but not limited to: CsPbCl3, CsPb(Cl/Br)3, CsPbBr3, CsPb(I/Br)3, CsPbl3, CH3NH3PbCl3, CH3NH3Pb(Cl/Br)3, CH3NH3PbBr3, CH3NH3Pb(I/Br)3, CH3NH3PbI3, and more. A plurality of examples on the nanoparticle material of perovskite may be referred to: Nano Lett., 2015, 15, 3692-3696; ACS Nano, 2015, 9, 4533-4542; Angewandte Chemie, 2015, 127(19): 5785-5788; Nano Lett., 2015, 15(4), pp 2640-2644; Adv. Optical Mater., 2014, 2, 670-678; The Journal of Physical Chemistry Letters, 2015, 6(3): 446-450; J. Mater. Chem. A, 2015, 3, 9187-9193; Inorg. Chem. 2015, 54, 740-745; RSC Adv., 2014, 4, 55908-55911; J. Am. Chem. Soc., 2014, 136(3), pp 850-853; Part. Part. Syst. Charact. 2015, doi: 10.1002/ppsc.201400214; Nanoscale, 2013, 5(19):8752-8780. All contents of the documents listed above are hereby incorporated for a reference.

In another preferred embodiment, the printing ink according to the present invention, wherein, the inorganic nano-material is a metal nanoparticle material. More preferably, the inorganic nano-material is a luminescent metal nanoparticle material.

The metal nanoparticle material includes but not limited to: nanoparticles of Cr, Mo, W, Ru, Rh, Ni, Ag, Cu, Zn, Pd, Au, Os, Re, Ir and Pt. A species, a morphology and a synthesis method of the metal nanoparticle material commonly seen may refer to Angew. Chem. Int. Ed. 2009, 48, 60-103; Angew. Chem. Int. Ed. 2012, 51, 7656-7673; Adv. Mater. 2003, 15, No. 5, 353-389, Adv. Mater. 2010, 22, 1781-1804; Small. 2008, 3, 310-325; Angew. Chem. Int. Ed. 2008, 47, 2-46, and more, as well as all references thereof. All contents of the documents listed above are hereby incorporated for a reference.

In another preferred embodiment, the inorganic nano-material has a property of charge transport.

In a preferred embodiment, the inorganic nano-material has a capability of an electron transport. Preferably, such an inorganic nano-material is selected from an n-type semiconductor material. An example of an n-type inorganic semiconductor material includes, but not limited to, a metal chalcogenide, a metal pnictide, or an elemental semiconductor, such as a metal oxide, a metal sulfide, a metal selenide, a metal telluride, a metal nitride, a metal phosphide, or a metal arsenide. Preferably, the n-type inorganic semiconductor material may be selected from: ZnO, ZnS, ZnSe, TiO2, ZnTe, GaN, GaP, AlN, CdSe, CdS, CdTe, CdZnSe, and any combinations thereof.

In a plurality of embodiments, the inorganic nano-material has a hole transport capability. Preferably, such an inorganic nano-material is selected from a p-type semiconductor material. An inorganic p-type semiconductor material may be selected from: NiOx, WOx, MoOx, RuOx, VOx, CuOx and any combinations thereof.

In a plurality of embodiments, the printing ink according to the present invention comprises at least two or more kinds of inorganic nano-materials.

In a plurality of embodiments, the printing ink according to the present invention further comprises at least one organic functional material. As described above, an object of the present invention is preparing an electronic device from a solution, due to a solubility in an organic solution and an inherent flexibility thereof, an organic material may be incorporated into a functional layer of an electronic device in a certain cases, and bringing a plurality of other benefits, such as enhancing a flexibility of the device, improving a performance of film-making and so on. As a principle, all organic functional materials applied for OLEDs, include but not limited to, hole injection material (HIM), hole transport material (HTM), electron transport material (ETM), electron injection material (EIM), electron blocking material (EBM), hole blocking material (HBM), light emitter (Emitter) and host material (Host) may all be applied in the printing ink of the present invention. Various organic functional materials are described in detail, for example, in WO2010135519A1 and US20090134784A1. All contents of the documents listed above are hereby incorporated for reference.

The present invention further relates to a method to prepare a thin film containing the nanoparticles through a method of printing or coating. In a preferred embodiment, the film containing nanoparticles is prepared through a method of ink jet printing. An ink jet printer applied to printing the ink containing the quantum dots according to the present invention may be a printer already commercially available, which contains a drop-on-demand printhead. Such a printer may be bought from Fujifilm Dimatix (Lebanon, N.H.), Trident International (Brookfield, Conn.), Epson (Torrance, Calif.), Hitachi Data systems Corporation (Santa Clara, Calif.), Xaar PLC (Cambridge, United Kingdom), and Idanit Technologies, Limited (Rishon Le Zion, Isreal). For example, the present invention may be printed by Dimatix materials Printer DMP-3000 (Fujifilm).

The present invention further relates to an electronic device, containing a layer or a plurality of layers of functional film, wherein at least one layer of functional film is prepared according to the printing ink composition of the present invention, specifically, prepared through a method of printing or coating.

A suitable electronic device includes but not limited to: a quantum dot light emitting diode (QLED), a quantum dot photovoltaic cell (QPV), a quantum dot light emitting electrochemical cell (QLEEC), a quantum dot field-effect transistor (QFET), a quantum dot light emitting field-effect transistor, a quantum dot laser, a quantum dot sensor and more.

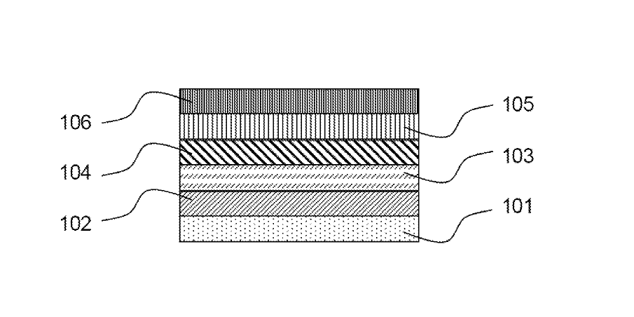

In a preferred embodiment, the electronic device listed above is an electroluminescent device, as shown in FIG. 1, the electroluminescent device comprises a substrate (101), an anode (102), at least a light emitting layer (104), a cathode (106).

The substrate (101) may be opaque or transparent. A transparent substrate can be applied to making a transparent light-emitting component. Refer to, for example, Bulovic et al. Nature 1996, 380, p 29, and Gu et al., Appl. Phys. Lett. 1996, 68, p 2606. A substrate material may be rigid or elastic. The substrate may be a plastic, a metal, a semiconductor wafer or a glass. Preferably, the substrate has a smooth surface. A substrate without any surface defects is a particularly desirable choice. In a preferred embodiment, the substrate is selected from a polymer film or a plastic, which has a glass transition temperature Tg of 150° C. or higher, preferably over 200° C., more preferably over 250° C. and most preferably over 300° C. An example of the suitable substrate is a poly (ethylene terephthalate) (PET) or a polyethylene glycol (2,6-naphthalene) (PEN).

The anode (102) may comprise a conductive metal or a metal oxide, or a conductive polymer. The anode may easily inject a hole into the HIL or HTL or the light-emitting layer. In an embodiment, an absolute value of the difference between the a work function of the anode and an HOMO level or a valence band level of the p-type semiconductor material working as HIL or HTL is less than 0.5 eV, preferably less than 0.3 eV, and most preferably, less than 0.2 eV. An example of an anode material includes, but not limited to, Al, Cu, Au, Ag, Mg, Fe, Co, Ni, Mn, Pd, Pt, ITO, aluminum-doped zinc oxide (AZO) and more. Other anode materials suitable are known and may be readily selected by an ordinary skilled man in the art. The anode material may be deposited using any suitable techniques, such as a suitable physical vapor deposition method, including a radio frequency magnetron sputtering deposition, a vacuum thermal evaporation deposition, an e-beam deposition, and more.

In a plurality of embodiments, the anode is a pattern structured. A patterned ITO conductive substrate is commercially available and may be applied to making devices according to the present invention.

The cathode (106) may comprise a conductive metal or a metal oxide. The cathode may easily inject an electron into the EIL or ETL or directly to the light-emitting layer. In an embodiment, an absolute value of the difference between the work function of the cathode and an LUMO level or a conduction band level of the n-type semiconductor material working as EIL or ETL or HBL is less than 0.5 eV, preferably less than 0.3 eV, and most preferably, less than 0.2 eV. Principally, all materials being able to be applied to a cathode of an OLED may be applied to that of the device according to the present invention. An example of a cathode material includes, but not limited to, Al, Au, Ag, Ca, Ba, Mg, LiF/Al, Mg—Ag alloy, BaF2/Al, Cu, Fe, Co, Ni, Mn, Pd, Pt, ITO and more. A cathode material may be deposited using any suitable techniques, such as a suitable physical vapor deposition method, including a radio frequency magnetron sputtering deposition, a vacuum thermal evaporation deposition, an e-beam deposition, and more.

The light emitting layer (104) contains at least one luminescent nano-material, with a thickness between 2 nm and 200 nm. In a preferred embodiment, a light-emitting device according to the present invention, wherein, the light-emitting layer thereof is prepared by printing the printing ink according to the present invention, while the printing ink contains a luminescent nano-material as described above, specifically a quantum dot.

In a preferred embodiment, the light-emitting device according to the present invention further comprises a hole injection layer (HIL) or a hole transport layer (HTL) (103) comprising an organic HTM or an inorganic p-type material. In a preferred embodiment, HIL or HTL may be prepared by printing the printing ink of the present invention, wherein the printing ink contains an inorganic nano-material having a hole-transport ability, specifically a quantum dot.

In another preferred embodiment, the light emitting device according to the present invention further comprises an electron injection layer (EIL) or an electron transport layer (ETL) (105), comprising the organic ETM or the inorganic n-type material described above. In a preferred embodiment, the EIL or ETL may be prepared by printing the printing ink of the present invention, wherein the printing ink contains an inorganic nano-material having an electron-transport ability, specifically a quantum dot.

The present invention further relates to an application of the light-emitting device according to the present invention in various cases including but not limited to, a plurality of various display devices, a plurality of backlights, a plurality of illuminating light sources and more.

The present invention will be described below with reference to a plurality of preferred embodiments, however, the present invention is not limited to the following embodiments. It should be understood that a plurality of claims appended have summarized a scope of the present invention, and under a guidance of the concept of the present invention, a technical personnel in the art should recognize that, a certain changes to the disclosed embodiments are intended to be encompassed within the scope of the claims of the present disclosure.

### EMBODIMENTS

### Embodiment 1: Preparing the Blue Light Quantum Dot (CdZnS/ZnS)

Weigh 0.0512 g of S and an amount of 2.4 mL ODE before putting in to a 25 mL one-necked flask, then place the flask into an oil pan before heated to 80° C. to dissolve the S, standby, hereinafter it is referred to solution 1; Weigh 0.1280 g of S and an amount of 5 mL OA before putting into a 25 mL one-necked flask, and then place the flask into an oil pan before heated to 90° C. to dissolve the S, standby, hereinafter it is referred to solution 2; Weigh 0.1028 g of CdO and 1.4680 g of zinc acetate, and an amount of 5.6 mL OA, before putting into a 50 mL three-necked flask, then place the three-necked flask in a 150 mL heating mantle, while plugging both necks on sides with two rubber plugs, and a condenser is connected above, the flask is then connected to a double-tube, before heated to 150° C., and evacuated for 40 minutes, and then purged with nitrogen. Using a syringe to add 12 mL ODE into the three-necked flask, before heated to 310° C., followed by injecting rapidly 1.92 mL solution 1 by a syringe into the three-necked flask, count for 12 min, add 4 mL of the solution 2 by drops into the three-necked flask with a syringe right after the 12 min, with a dropping rate about 0.5 mL/min, wait for a reaction lasting 3 h, before stopping the reaction, and put the three-necked flask immediately in water to cool down to 150° C.;

Add an excess n-hexane into the three-necked flask, then transfer a liquid in the three-necked flask to a plurality of centrifuge tubes of 10 mL, centrifuge and remove a lower sediment, repeat for three times; add acetone to the liquid after the treatment to produce a precipitate, centrifuge and remove a supernatant, with a precipitate leaving; followed by using an n-hexane to dissolve the precipitate, and adding acetone for precipitating, centrifuge and remove a supernatant, with a precipitate leaving, repeat for three times; finally, dissolve the precipitate with a toluene before transferring to a glass bottle for storage.

### Embodiment 2: Preparing the Green Light Quantum Dot (CdZnSeS/ZnS)

Weigh 0.0079 g of Se and 0.1122 g of S before putting into a 25 mL one-necked flask, and an amount of 2 mL TOP, purged with nitrogen, stir and standby, thereafter it is referred to solution 1; weight 0.0128 g of CdO and 0.3670 g of Zinc acetate, and an amount of 2.5 mL OA before putting into a 25 mL three-necked flask, while plugging both necks on sides with two rubber plugs, and a condenser is connected above, the flask is then connected to a double-tube, followed by placing the three-necked flask into a 50 mL heating mantle, evacuate and purge with nitrogen, before heated to 150° C., and evacuated for 30 min, injected with 7.5 mL of ODE, and heated to 300° C., followed by injecting rapidly 1 mL solution 1, count for 10 min; stop the reaction right after 10 min, and place the three-necked flask into water for cooling.

Add 5 mL n-hexane into the three-necked flask, then transfer a mixture in the three-necked flask into a plurality of centrifuge tubes of 10 mL, add acetone to produce a precipitate, and centrifuge. Repeat for three times. And, at last, the participate is dissolved with a small amount of toluene, before transferring to a glass bottle for storage.

### Embodiment 3: Preparing the Red Light Quantum Dot (CdSe/CdS/ZnS)

Add 1 mmol of CdO, 4 mmol of OA and 20 mL ODE into a 100 mL three-necked flask, purge with nitrogen, heat to 300° C. and a precursor of Cd(OA)2 is formed. At such a temperature, inject rapidly 0.25 mL of TOP with 0.25 mmol Se powder dissolved. React for 90 seconds at such a temperature, a reaction solution grows for a 3.5 nm CdSe core. Add 0.75 mmol of octylmercaptan into the reaction solution by drops at a temperature of 300° C., react for 30 min and a CdS shell with about 1 nm thickness is grown. Followed by adding 4 mmol of Zn(OA)2 and 2 ml TBP with 4 mmol S powder dissolved into the reaction solution by drops, to grow a ZnS shell (about 1 nm). The reaction lasts for 10 minutes before cooling to a room temperature.

Add 5 mL n-hexane into the three-necked flask, then transfer a mixture in the three-necked flask into a plurality of centrifuge tubes of 10 mL, add acetone to produce a precipitate, and centrifuge. Repeat for three times. And, at last, the participate is dissolved with a small amount of toluene, before transferring to a glass bottle for storage.

### Embodiment 4: Preparing the ZnO Nanoparticle

Dissolve 1.475 g of zinc acetate in 62.5 mL of methanol, and obtain a solution 1. Dissolve 0.74 g of KOH in 32.5 mL of methanol, and obtain a solution 2. Heat the solution 1 up to 60° C. and stir vigorously. Add the solution 2 by drops into the solution 1 using a sampler. After completed, the mixture is kept stirring for 2 hours at 60° C. Remove the heat source and leave the solution system undisturbed for 2 hours. Under a centrifugation condition of 4500 rpm, 5 min, wash the reaction solution by centrifugation three times or more. And the finally obtained of a white solid is the ZnO nanoparticle with a diameter of about 3 nm.

### Embodiment 5: Preparing the Printing Ink with the Quantum Dots Containing the Dodecylbenzene

Put a stirrer into a vial, clean it up before transferring to a glove box. In the vial, prepare 9.5 g of dodecylbenzene. Precipitate the quantum dots from the solution with acetone, centrifuge and obtain a solid of the quantum dots. Weigh for 0.5 g of the solid of the quantum dots from the glove box, add to the solvent system in the vial, stir and mix. Keep stirring at a temperature of 60° C. until the quantum dots fully dispersed, cool to the room temperature. Membrane Filtrate the quantum dot solution obtained through a 0.2 μm PTFE filter. Seal and store.

### Embodiment 6: Preparing the Printing Ink with the Quantum Dots Containing the 1-Methoxynaphthalene

Put a stirrer into a vial, clean it up before transferring to a glove box. In the vial, prepare 9.5 g of 1-methoxynaphthalene. Precipitate the quantum dots from the solution with acetone, centrifuge and obtain a solid of the quantum dots. Weigh for 0.5 g of the solid of the quantum dots from the glove box, add to the solvent system in the vial, stir and mix. Keep stirring at a temperature of 60° C. until the quantum dots fully dispersed, cool to the room temperature. Membrane Filtrate the quantum dot solution obtained through a 0.2 μm PTFE filter. Seal and store.

### Embodiment 7: Preparing the Printing Ink with the Quantum Dots Containing the Cyclohexylbenzene

Put a stirrer into a vial, clean it up before transferring to a glove box. In the vial, prepare 9.5 g of cyclohexylbenzene. Precipitate the quantum dots from the solution with acetone, centrifuge and obtain a solid of the quantum dots. Weigh for 0.5 g of the solid of the quantum dots from the glove box, add to the solvent system in the vial, stir and mix. Keep stirring at a temperature of 60° C. until the quantum dots fully dispersed, cool to the room temperature. Membrane Filtrate the quantum dot solution obtained through a 0.2 μm PTFE filter. Seal and store.

### Embodiment 8: Preparing the Printing Ink with the Quantum Dots Containing the 3-Isopropylbiphenyl

Put a stirrer into a vial, clean it up before transferring to a glove box. In the vial, prepare 9.5 g of 3-isopropylbiphenyl. Precipitate the quantum dots from the solution with acetone, centrifuge and obtain a solid of the quantum dots. Weigh for 0.5 g of the solid of the quantum dots from the glove box, add to the solvent system in the vial, stir and mix. Keep stirring at a temperature of 60° C. until the quantum dots fully dispersed, cool to the room temperature. Membrane Filtrate the quantum dot solution obtained through a 0.2 μm PTFE filter. Seal and store.

### Embodiment 9: Preparing the Printing Ink with the Quantum Dots Containing the Benzyl Benzoate

Put a stirrer into a vial, clean it up before transferring to a glove box. In the vial, prepare 9.5 g of benzyl benzoate. Precipitate the quantum dots from the solution with acetone, centrifuge and obtain a solid of the quantum dots. Weigh for 0.5 g of the solid of the quantum dots from the glove box, add to the solvent system in the vial, stir and mix. Keep stirring at a temperature of 60° C. until the quantum dots fully dispersed, cool to the room temperature. Membrane Filtrate the quantum dot solution obtained through a 0.2 μm PTFE filter. Seal and store.

### Embodiment 10: Preparing the Printing Ink with the Quantum Dots Containing the 1-Tetralone

Put a stirrer into a vial, clean it up before transferring to a glove box. In the vial, prepare 9.5 g of 1-tetralone. Precipitate the quantum dots from the solution with acetone, centrifuge and obtain a solid of the quantum dots. Weigh for 0.5 g of the solid of the quantum dots from the glove box, add to the solvent system in the vial, stir and mix. Keep stirring at a temperature of 60° C. until the quantum dots fully dispersed, cool to the room temperature. Membrane Filtrate the quantum dot solution obtained through a 0.2 μm PTFE filter. Seal and store.

### Embodiment 11: Preparing the Printing Ink with the Quantum Dots Containing the 3-Phenoxytoluene

Put a stirrer into a vial, clean it up before transferring to a glove box. In the vial, prepare 9.5 g of 3-phenoxytoluene. Precipitate the quantum dots from the solution with acetone, centrifuge and obtain a solid of the quantum dots. Weigh for 0.5 g of the solid of the quantum dots from the glove box, add to the solvent system in the vial, stir and mix. Keep stirring at a temperature of 60° C. until the quantum dots fully dispersed, cool to the room temperature. Membrane Filtrate the quantum dot solution obtained through a 0.2 μm PTFE filter. Seal and store.

### Embodiment 10: A Test of the Viscosity and the Surface Tension

The viscosity of the printing ink with the quantum dots was measured by a DV-I Prime Brookfield rheometer; the surface tension of the printing ink with the quantum dots was measured by a SITA bubble pressure tensiometer.

From the tests described above, the viscosity of the printing ink with the quantum dots obtained in the example 5 is 6.2±0.1 cPs, the surface tension is 29.1±0.1 dyne/cm.

From the tests described above, the viscosity of the printing ink with the quantum dots obtained in the example 6 is 8.3±0.3 cPs, the surface tension is 39.2±0.5 dyne/cm.

From the tests described above, the viscosity of the printing ink with the quantum dots obtained in the example 7 is 5.5±0.3 cPs, the surface tension is 32±0.1 dyne/cm.

From the tests described above, the viscosity of the printing ink with the quantum dots obtained in the example 8 is 9.8±0.5 cPs, the surface tension is 32.1±0.1 dyne/cm.

From the tests described above, the viscosity of the printing ink with the quantum dots obtained in the example 9 is 9.1±0.1 cPs, the surface tension is 39.4±0.3 dyne/cm.

From the tests described above, the viscosity of the printing ink with the quantum dots obtained in the example 10 is 9.3±0.3 cPs, the surface tension is 38.1±0.5 dyne/cm.

From the tests described above, the viscosity of the printing ink with the quantum dots obtained in the example 11 is 6.7±0.3 cPs, the surface tension is 33.1±0.1 dyne/cm.

Using the above prepared printing ink of the solvent system comprising the substituted aromatic-based or substituted heteroaromatic-based organic solvent containing the quantum dots, through a method of ink-jet printing, the functional layers in the quantum dot light-emitting diode may be prepared, including the light-emitting layer and the charge transport layer, the specific steps are as follows.

Put the ink containing the quantum dots into an ink tank, and mount the ink tank onto an ink jet printer such as a Dimatix Materials Printer DMP-3000 (Fujifilm). Adjust a waveform, a pulse time and a voltage of jetting the ink, before achieving a best of the ink spray, and a stability of the ink spray range. When preparing a QLED device with a quantum dot film as a light-emitting layer, the following technical solution is adopted: The substrate of the QLED is 0.7 mm-thick glass sputtered with an indium tin oxide (ITO) electrode pattern. On the ITO, a pixel definition layer is patterned to form a plurality of holes for depositing the printing ink inside. Followed by obtaining a HIL/HTL film through ink-jet printing the HIL/HTL material into the holes, and removing the solvent by drying under a high temperature in a vacuum environment. Followed by ink-jet printing the printing ink containing the light emitting quantum dots onto the HIL/HTL film, and removing the solvent by high-temperature drying in a vacuum environment to obtain a quantum dots light-emitting layer film. Followed by ink-jet printing the printing ink containing the quantum dots having the electron transporting property onto the light-emitting layer thin film, and removing the solvent by high-temperature drying in a vacuum environment, to form an electron transport layer (ETL). When using the organic electronic transmission materials, the ETL may also be formed by vacuum thermal evaporation. Then, the Al cathode is formed by vacuum thermal evaporation, and finally the QLED device preparation is completed and packaged.

It should be understood that the above embodiments disclosed herein are exemplary only and not limiting the scope of this disclosure. Without departing from the spirit and scope of this invention, other modifications, equivalents, or improvements to the disclosed embodiments are obvious to those skilled in the art and are intended to be encompassed within the scope of the present disclosure.

What is claimed is:

1. A printing ink composition, comprises at least one inorganic nano-material and at least one substituted aromatic-based or substituted heteroaromatic-based organic solvent shown as a general formula below: 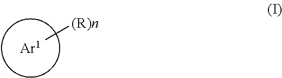
wherein, Ar¹ is an aromatic or heteroaromatic ring having 5˜10 carbon atoms, n≥1, R is a substituent, and a total number of atoms other than H of any substituent is equal to or greater than 2, wherein the organic solvents has a boiling point 180° C., the organic solvent may be evaporated from a solvent system, forming a thin film of inorganic nano-materials.

2. The printing ink composition according to claim 1, wherein the organic solvent has a viscosity in a range of 1 cPs to 100 cPs at 25° C.

3. The printing ink composition according to claim 1, wherein the organic solvent has a surface tension in a range of 19 dyne/cm to 50 dyne/cm at 25° C.

4. The printing ink composition according to claim 1, wherein the organic solvent has a structure shown as a general formula below: 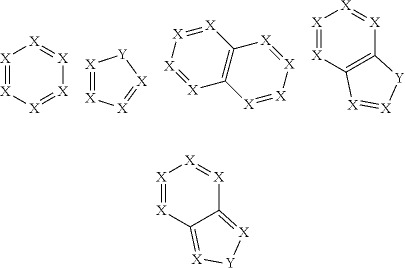
wherein,
X is CR¹ or N;
Y is selected from CR²R³, SiR²R³, NR² or, C(═O), S, or O;
R¹, R², R³ is a Hydrogen, a Deuterium, or a linear alkyl, alkoxy or thioalkoxy group having 1 to 20 of C atoms, or a branched or cyclic alkyl, alkoxy or thioalkoxy group or a silyl group having 3 to 20 of C atoms, or a substituted keto group having 1 to 20 of C atoms, an alkoxycarbonyl group having 2 to 20 of C atoms, an aryloxycarbonyl group having 7 to 20 of C atoms, a cyano group (—CN), a carbamoyl group (—C(═O)NH₂), a haloformyl group (—C(═O)—X, wherein X represents a halogen atom), a formyl group (—C(═O)—H), an isocyano group, an isocyanate group, a thiocyanate group or an isothiocyanate group, a hydroxyl group, a nitro group, a CF₃ group, a Chlorine, a Bromine, a Fluorine, a crosslinkable group or a substituted or unsubstituted aromatic or heteroaromatic ring system having 5 to 40 ring atoms, or an aryloxy or a heteroaryloxy group having 5 to 40 ring atoms, or a combination thereof, wherein one or more groups of R¹, R², R³ may form a mono or polycyclic aliphatic or aromatic ring system by themselves and/or rings bonded with the groups.

5. The printing ink composition according to claim 1, wherein the Ar¹ in the general formula (I) is selected from any one of a plurality of structural units below:

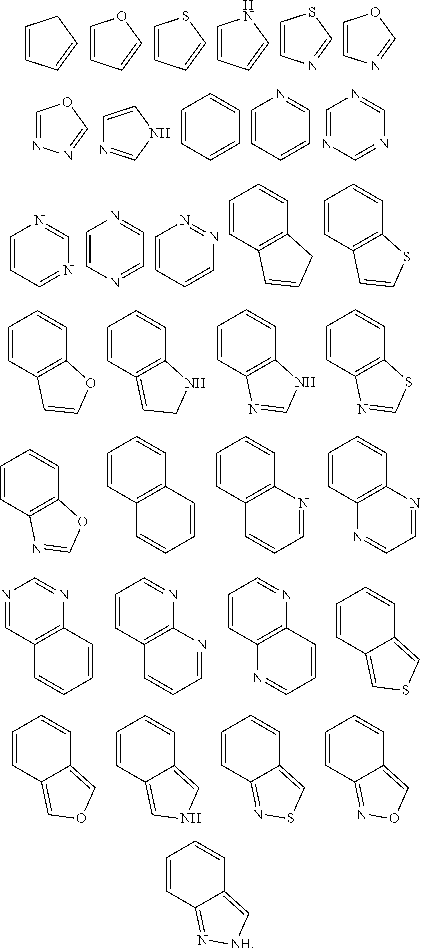

6. The printing ink composition according to claim 1, wherein the R in the general formula (I) is selected from a linear alkyl, alkoxy or thioalkoxy group having 1 to 20 of C atoms, or a branched or cyclic alkyl, alkoxy or thioalkoxy group or a silyl group having 3 to 20 of C atoms, or a substituted keto group having 1 to 20 of C atoms, an alkoxycarbonyl group having 2 to 20 of C atoms, an aryloxycarbonyl group having 7 to 20 of C atoms, a cyano group (—CN), a carbamoyl group (—C(═O)NH2), a haloformyl group (—C(═O)—X, wherein X represents a halogen atom), a formyl group (—C(═O)—H), an isocyano group, an isocyanate group, a thiocyanate group or an isothiocyanate group, a hydroxyl group, a nitro group, a CF₃ group, a Chlorine, a Bromine, a Fluorine, a crosslinkable group or a substituted or unsubstituted aromatic or heteroaromatic ring system having 5 to 40 ring atoms, or an aryloxy or a heteroaryloxy group having 5 to 40 ring atoms, or a combination thereof, wherein one or more groups of R may form a mono or polycyclic aliphatic or aromatic ring system by themselves and/or rings bonded with the groups.

7. The printing ink composition according to claim 1, wherein the organic solvent is selected from: a dodecylbenzene, a dipentylbenzene, a diethylbenzene, a trimethylbenzene, a tetramethylbenzene, a butylbenzene, a tripentylbenzene, a pentyltoluene, a 1-methylnaphthalene, a dibutylbenzene, a p-diisopropylbenzene, a pentylbenzene, a tetralin, a cyclohexylbenzene, a chloronaphthalene, a 1-tetralone, a 3-phenoxytoluene, a 1-methoxynaphthalene, a cyclohexylbenzene, a dimethylnaphthalene, a 3-isopropylbiphenyl, a p-cumylbenzene, a benzyl benzoate, a dibenzyl ether, a benzyl benzoate, or any combination thereof.

8. The printing ink composition according to claim 1, wherein the organic solvent may further include at least one other solvent, while the organic solvent in the general formula (I) occupies above 50% of a total weight of a mixed solvent.

9. The printing ink composition according to claim 1, wherein the inorganic nano-material is a quantum dot material, that is, a particle diameter thereof has a monodisperse size distribution, and a shape thereof may be selected from a plurality of different forms, including a sphere, a cube, a rod or a branched structure.

10. The printing ink composition according to claim 1, wherein at least one luminescent quantum dot material is comprised, with a luminescence wavelength between 380 nm and 2500 nm.

11. The printing ink composition according to claim 1, wherein the at least one inorganic nano-material is a binary or multiple semiconductor compound or a mixture thereof, in Group IV, Group II-VI, Group II-V, Group III-V, Group III-VI, Group IV-VI, Group I-III-VI, Group II-IV-VI, Group II-IV-V of the Periodic Table.

12. The printing ink composition according to claim 1, wherein the at least one inorganic nano-material is a luminescent quantum dot, selected from CdSe, CdS, CdTe, ZnO, ZnSe, ZnS, ZnTe, HgS, HgSe, HgTe, CdZnSe, and any combinations thereof.

13. The printing ink composition according to claim 1, wherein the at least one inorganic nano-material is a luminescent quantum dot, selected from InAs, InP, InN, GaN, InSb, InAsP, InGaAs, GaAs, GaP, GaSb, AlP, AlN, AlAs, AlSb, CdSeTe, ZnCdSe and any combinations thereof.

14. The printing ink composition according to claim 1, wherein the at least one inorganic nano-material is a nanoparticle material of perovskite, specifically a luminescent nanoparticle material of perovskite, or a metal nanoparticle material, or a metal oxide nanoparticle material, or a plurality of combinations thereof.

15. The printing ink composition according to claim 1, wherein an organic functional material is further comprised, the organic functional material may be selected from a hole injection material (HIM), a hole transport material (HTM), an electron transport materials (ETM), an electron injection material (EIM), an electrons blocking material (EBM), a hole blocking material (HBM), a light emitter (Emitter) and a host material (Host).

16. The printing ink composition according to claim 1, wherein a weight ratio of the inorganic nano-material is 0.3%˜70%, a weight ratio of the organic solvent contained is 30%˜99.7%.

17. An electronic device, comprises a functional layer printed by the printing ink composition according to claim 1, wherein the substituted aromatic-based or substituted heteroaromatic-based organic solvent comprised in the combination may be evaporated from the solvent system, forming a thin film comprising the inorganic nano-materials.

18. The electronic device according to claim 17, wherein the electronic device is selected from a quantum dot light emitting diode (QLED), a quantum dot photovoltaic cell (QPV), a quantum dot light emitting electrochemical cell (QLEEC), a quantum dot field-effect transistor (QFET), a quantum dot luminescent field-effect transistor, a quantum dot Laser, a quantum dot sensor.
